(19) United States
(12) Patent Application Publication
(10) Pub. No.: US 2026/0094796 A1
(43) Pub. Date: Apr. 2, 2026

(54) SUBSTRATE PROCESSING APPARATUS

(71) Applicant: SAMSUNG ELECTRONICS CO., LTD., Suwon-si (KR)

(72) Inventors: Namjin Cho, Suwon-si (KR); Hyeonggyu Kim, Suwon-si (KR); Yihwan Kim, Suwon-si (KR); Jihye Lee, Suwon-si (KR); Seyeong Jin, Suwon-si (KR)

(21) Appl. No.: 19/083,071

(22) Filed: Mar. 18, 2025

(30) Foreign Application Priority Data
Sep. 27, 2024 (KR) 10-2024-0132146

(51) Int. Cl. H01J 37/34

(52) U.S. Cl. CPC H01J 37/3444; H01J 37/3426; H01J 37/3435; H01J 37/345; H01J 37/3467; H01J 37/347; H01J 2237/3323

(57) ABSTRACT

A substrate processing apparatus is described. The substrate processing apparatus includes a chamber in which a substrate processing process is performed, a substrate support placed inside the chamber and configured to support a substrate, a target placed to face the substrate, a target holder connected to the target, a non-sinusoidal bias supply configured to provide a periodic non-sinusoidal bias to the substrate support, a DC power supply configured to apply a DC power to the target through the target holder, and a controller configured to control a waveform of the periodic non-sinusoidal bias. The periodic non-sinusoidal bias includes, within one cycle, a pulse period where a voltage is maintained constantly and a ramp period where a voltage gradually changes.

### CROSS-REFERENCE TO RELATED APPLICATION(S)

This application is based on and claims priority to Korean Patent Application No. 10-2024-0132146, filed in the Korean Intellectual Property Office on Sep. 27, 2024, the entire contents of which are hereby incorporated by reference.

### BACKGROUND

The present disclosure is related to a substrate processing apparatus.

Semiconductor devices have been formed through various manufacturing processes such as a deposition process, an ion implantation process, a photolithography process, an etching process, etc. As the integration and miniaturization of devices progress, the requirements for the quality and thickness uniformity of metal film have been in high demand. It is possible to enhance the properties of the thin film by applying a high-frequency bias power to a substrate to increase ion energy. However, increasing the high-frequency power may lead to a deterioration in the thickness uniformity of the thin films. Accordingly, various methods have been studied to stably form fine patterns and deposit thin films of high quality.

The above-described information is only to improve the understanding of the background of the present disclosure but may include information that is not relevant to conventional technology.

### SUMMARY

The present disclosure is aimed to provide a substrate processing apparatus for solving the above-described problem.

The problems to be solved are not limited the above, but the other tasks not mentioned above may be explicitly known to those skilled in the art from the description of the present disclosure below.

According to implementations of the present disclosure, there is provided a substrate processing apparatus, comprising a chamber configured to maintain a substrate processing process, a substrate support inside the chamber and configured to support a substrate, a target within the chamber and facing the substrate, a target holder connected to the target, a non-sinusoidal bias supply configured to provide a periodic non-sinusoidal bias to the substrate support, a DC power supply configured to apply a DC power to the target through the target holder, and a controller configured to control a waveform of the periodic non-sinusoidal bias, wherein the periodic non-sinusoidal bias includes, within one cycle, a pulse period during which a voltage is maintained constantly and a ramp period during which the voltage gradually changes.

According to implementations of the present disclosure, the controller may be configured to determine a non-sinusoidal parameter including a positive voltage value and a negative voltage value of the pulse period, a voltage value of the ramp period, and a voltage application time.

According to implementations of the present disclosure, the controller may be configured to control a ratio of a voltage application time of the ramp period to an entire voltage application time of the cycle to be within a range from 45% to 55%.

According to implementations of the present disclosure, the controller may be configured to control a positive voltage of the pulse period to be within a range from 10V to 50V.

According to implementations of the present disclosure, the controller may be configured to control a negative voltage of the pulse period to be within a range from −50V to −130V.

According to implementations of the present disclosure, the controller may be configured to control a duty cycle to be within a range from 40% to 60%, wherein the duty cycle is a ratio between an active state of the periodic non-sinusoidal bias and a non-active state.

According to implementations of the present disclosure, the controller may be configured to control a waveform of the periodic non-sinusoidal bias based on a dispersion of particles of the target deposited to the substrate.

According to implementations of the present disclosure, the target may include at least one of copper, titanium, or tungsten.

According to implementations of the present disclosure, the substrate processing process may include a deposition process.

According to implementations of the present disclosure, the substrate processing apparatus may further include an RF bias supply configured to provide an RF bias to the substrate support.

According to implementations of the present disclosure, the controller may be configured to control the RF bias supply to allow the RF bias to be applied to the substrate support, and to control the non-sinusoidal bias supply to allow the periodic non-sinusoidal bias to be applied to the substrate support.

According to implementations of the present disclosure, the DC power supply is configured to bias the target as a cathode.

According to implementations of the present disclosure, the substrate processing apparatus may further include an RF bias supply configured to provide an RF bias to the target holder.

According to implementations of the present disclosure, the controller may be configured to control the DC power supply to allow the DC power to be applied to the target holder and to control the RF bias supply to allow the RF bias to be applied to the target holder.

According to implementations of the present disclosure, the substrate processing apparatus may further include a permanent magnet adjacent to the target holder.

According to implementations of the present disclosure, the substrate processing apparatus may further include a process gas supply configured to provide a plasma process gas inside the chamber.

According to implementations of the present disclosure, the plasma process gas may include argon or krypton.

According to implementations of the present disclosure, the substrate processing apparatus may be placed between the non-sinusoidal bias supply and the substrate support, and may further include a non-sinusoidal filter configured to selectively filter a frequency component of the periodic non-sinusoidal bias.

According to implementations of the present disclosure, there is provided a substrate processing apparatus, including a chamber configured to maintain a deposition process, a substrate support inside the chamber and configured to support a substrate, a target, within the chamber and facing the substrate, a target holder connected to the target, a permanent magnet adjacent to the target holder, a non-sinusoidal bias supply that provides a periodic non-sinusoidal bias to the substrate support, a DC power supply configured to apply a DC power to the target through the target holder, and a controller configured to control a waveform of the periodic non-sinusoidal bias, wherein the periodic non-sinusoidal bias includes, within one cycle, a pulse period during which a voltage is constantly maintained, and a ramp period during which the voltage gradually changes within, and wherein the controller is configured to control a non-sinusoidal parameter including a positive voltage value and a negative voltage value of the pulse period, a voltage value of the ramp period, and a voltage application time.

According to implementations of the present disclosure, there is provided a substrate processing apparatus, including a chamber configured to maintain a deposition process, a substrate support inside the chamber and configured to support a substrate, a target, within the chamber, facing the substrate, a target holder connected to the target, a permanent magnet adjacent to the target holder, a non-sinusoidal bias supply configured to provide a periodic non-sinusoidal bias to the substrate support, a non-sinusoidal filter placed between the non-sinusoidal bias supply and the substrate support and configured to selectively filter a frequency component of the non-sinusoidal bias, a DC power supply configured to apply a DC power to the target through the target holder, an RF bias supply configured to provide an RF bias to the target holder or to the substrate support, and a controller configured to control a waveform of the periodic non-sinusoidal bias, wherein the periodic non-sinusoidal bias includes, within one cycle, a pulse period during which a voltage is constantly maintained, and a ramp period during which the voltage gradually changes, and wherein the controller is configured to control a non-sinusoidal parameter including a positive voltage value and a negative voltage value of the pulse period, a voltage value of the ramp period, and a voltage application time.

According to implementations of the present disclosure, the uniformity of the thin film deposited on the substrate may be improved by providing a physical deposition apparatus that applies a DC power to a target and a periodic non-sinusoidal bias to a substrate support.

According to implementations of the present disclosure, the plasma density and ion energy distribution may be efficiently managed by adjusting the periodic non-sinusoidal bias applied to the substrate support and meticulously controlling a parameter. Therefore, the desired thin film characteristic may be ensured and the degree of precision of the process may be improved.

According to implementations of the present disclosure, the RF bias and the periodic non-sinusoidal bias may be selectively applied by connecting an RF bias supply to a non-sinusoidal bias supply to a substrate support, thereby optimizing the deposition characteristics of the thin film, enhancing the flexibility of the process, and forming the thin film of the high quality.

According to implementations of the present disclosure, the DC power and the periodic non-sinusoidal bias may be selectively applied by connecting a DC power and an RF bias to a target holder. This may correspond to various target materials and process conditions. The uniformity and the quality of the deposited thin film may be improved by meticulously controlling the ion energy distribution in the plasma by applying a periodic non-sinusoidal bias to the substrate support.

The effect that is obtained from the present disclosure is not limited the above. The technical effect not mentioned above may be explicitly known to those skilled in the art from the description below.

### BRIEF DESCRIPTION OF DRAWINGS

FIG. 1 is a view illustrated to explain a substrate processing apparatus according to implementations of the present disclosure;

FIG. 2 is an exemplary view illustrating a non-sinusoidal voltage waveform according to implementations of the present disclosure;

FIG. 3 illustrates graphs according to an application ratio of a ramp period;

FIG. 4 illustrates steps of a deposition process using a substrate processing apparatus according to implementations of the present disclosure;

FIG. 5 is a view illustrating a result of a resistivity test for a deposition layer in FIG. 4 and a reference deposition layer;

FIG. 6 is a view illustrating a test result of a deposition thickness for the deposition layer of FIG. 4 and the reference deposition layer;

FIG. 7 is a view illustrating a test result of a deposition thickness dispersion for the deposition layer of FIG. 4 and the reference deposition layer;

FIG. 8 is a view illustrating a substrate processing apparatus according to implementations of the present disclosure;

FIG. 9 is a view illustrating a substrate processing apparatus according to implementations of the present disclosure;

FIG. 10 is a view illustrating a substrate processing apparatus according to implementations of the present disclosure; and

FIG. 11 is a view illustrating a substrate processing apparatus according to implementations of the present disclosure.

Implementations of the technical spirit of the present disclosure will be described in detail with reference to the attached drawings. Like reference numerals in the drawings denote like elements, and the redundant description will be omitted.

### DETAILED DESCRIPTION

An electrostatic chuck and a substrate processing apparatus including the same will be described in detail with reference to the attached drawings. Like reference numerals in the drawings denote like elements, and the size of each element is illustrated in the drawings may be exaggerated for clarity and ease of explanation. The implementations described below are only exemplary, but it is to be understood that various changes and modifications may be made to implementations of the present disclosure without departing from the spirit and scope of the invention.

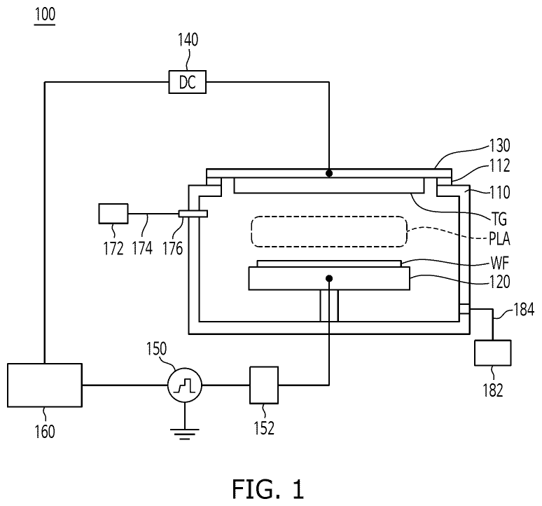

FIG. 1 is a view illustrated to explain a substrate processing apparatus 100 according to implementations.

The substrate processing apparatus 100 may be an apparatus that performs a process a substrate WF for manufacturing a semiconductor device by using plasma PLA. For example, the substrate processing apparatus 100 may be a capacitively coupled plasma apparatus, an inductively coupled plasma apparatus or a microwave plasma apparatus.

According to implementations, the substrate processing apparatus 100 may be an apparatus that uses a Physical Vapor Deposition (PVD) method to deposit desired materials on the substrate WF. Various sputtering methods may be applied to the substrate processing apparatus 100. For example, the various sputtering methods may include DC sputtering, RF sputtering, magnetron sputtering, high-power pulsed magnetron sputtering (HiPIMS) methods. Each of the methods may be selected according to the types of target materials, processing conditions, deposition characteristics, etc. and the designs and operation conditions of the apparatus may vary accordingly. The present disclosure is not limited to the specific methods as described above, but other sputtering methods may be applied.

According to implementations, the substrate WF may be a semiconductor substrate to form fine patterns for semiconductor devices. For example, the substrate WF may be a semiconductor substrate including silicon or germanium. For another example, the substrate WF may be a silicon on insulator (SOI) substrate. According to yet another example, the substrate WF may be a glass substrate.

Referring to FIG. 1, the substrate processing apparatus 100 may include a chamber 110, a substrate support 120, a target holder 130, a target TG, a DC power supply 140, a non-sinusoidal bias supply 150, a non-sinusoidal bias filter 152, a controller 160, a process gas supply 172, a gas supply line 174, a gas inlet nozzle 176, a vacuum pump 182, and an exhaust pipe 184.

The chamber 110 may provide a space for performing a substrate processing process in a vacuum state. The inside of the chamber 110 may be sealed to control a process environment. The pressure, the temperature, and the gas flow inside the chamber may be controlled by a separate control system (e.g., a controller 160). The chamber 110 may be made of durable materials to be maintained in a high vacuum state. For example, the chamber 110 may include metals such as aluminum and stainless steel, but the present disclosure is not limited thereto.

The substrate support 120 may be configured to stably fix the substrate WF to ensure a uniform deposition on the substrate during the process. The substrate support 120 may be disposed inside the chamber 110. The substrate WF may be disposed on the top of the substrate support 120. The substrate support 120 may be electrostatic chuck for fixing the substrate WF in an electrostatic chuck method. The substrate support 120 may include an adsorption electrode inside, and the substrate WF may be fixed by an electrostatic chuck through the application of a voltage to the adsorption electrode. The substrate support 120 may include ceramic or metal with high thermal conductivity or, materials that have both high electrical insulation and thermal conductivity.

The substrate support 120 may include an electrode structure inside and may be connected to the non-sinusoidal bias supply 150. The density and ion energy of the plasma PLA may be precisely controlled through the non-sinusoidal bias control. Unlike the conventional RF bias, the non-sinusoidal bias may more accurately adjust the density and ion energy of the plasma PLA by using the non-sinusoidal bias waveform. For example, the controller 160 may control the non-sinusoidal bias waveform to adjust the density and ion energy of the plasma PLA to ensure uniform deposition on the substrate. The substrate support 120 may be connected to a power supply (e.g., a DC power) to electrostatically fix the substrate WF disposed on the substrate support 120. An electric field generated by the applied power supply may generate an electrostatic attraction between the electrostatic chuck and the substrate to stably fix the substrate on a surface of the substrate support 120 during the process.

The target holder 130 may fix the target TG, which is a deposition material, in the PVD process. The target TG may have a disc shape or a rectangular shape, but it is not limited thereto. The target TG may be a source material to be deposited on the surface of the substrate WF and may include metals or metal alloys such as copper (Cu), aluminum (Al), titanium (Ti), or tungsten (W), but it is not limited thereto. The target holder 130 may be designed to endure the heat and stress generated during the sputtering in the target TG. The target holder 130 may be biased as a cathode by a DC bias applied from the DC power supply 140 to function as a cathode. The target holder 130 may be electrically insulated with the chamber 110 through the insulating member 112. The insulating member 112 may be placed between the target holder 130 and the chamber 110, so that the target holder 130 may be electrically isolated to allow a voltage to be applied to the target TG.

Referring to FIG. 1, the target holder 130 may have a plate shape, and the target TG fixed may be fixed to a surface of the target holder 130. However, the present disclosure is not limited thereto, but may be designed in various shapes to fix the target TG. For example, the target holder 130 may have a structure that surrounds the target TG.

The DC power supply 140 may be connected to the target TG to supply power. For example, the DC power supply 140 may apply a DC negative power or a DC bias to the target. According to implementations, the DC power supply 140 may supply a power to the target TG through the target holder 130. When the DC voltage is applied to the target TG, process gas for sputter discharge that is supplied to the inside of the chamber 110 through the process gas supply 170 may be ionized to form the plasma PLA. The ionized gas ions may be accelerated and collide with the cathode-biased target TG, and thus the atoms on the surface of the target TG may be sputtered and ejected. The ejected atoms may be deposited on the substrate WF. The DC power supply 140 may be linked to the controller 160 to supply a stable power to the target TG to allow the target material to be consistently ejected. Therefore, the deposition rate and the thin film thickness may be adjusted by precisely controlling a voltage and a current.

The non-sinusoidal bias supply 150 may supply a power to the substrate support 120 to control the density and ion energy of the plasma PLA. The non-sinusoidal bias may have a complex waveform unlike a conventional DC power supply, which changes the characteristics of the plasma PLA and improves the deposition quality.

The basic frequency of the non-sinusoidal bias may be in a range from approximately 100 kHz to 2 MHz. The non-sinusoidal bias may have a square wave form or a pulse wave form, and may include 3rd, 5th, and 7th harmonic components in addition to the basic frequency. Each harmonic component may be a multiple of the basic frequency, and the density and ion energy of the plasma PLA may be controlled more precisely through various frequency components. For example, when the basic frequency is about 400 kHz, the 3rd harmonic may be about 1.2 MHz, the 5th harmonic may be about 2.0 MHz, and the 7th harmonic may be about 2.8 MHz. Such harmonic components may be selectively adjusted through a non-sinusoidal filter 152, and the characteristics of the plasma PLA may be changed depending on the harmonic ratio.

The plasma PLA may be uniformly and stably maintained during the process by supplying the non-sinusoidal bias power to the substrate support 120. The non-sinusoidal filter 152 may include a capacitor and a coil, and selectively filter the frequency components of the non-sinusoidal bias to pass the signals in a specific frequency bandwidth, thereby minimizing signal distortion or electromagnetic interference during the process.

The controller 160 may control each component of the substrate processing apparatus 100. The controller 160 may precisely adjust the operations of the components connected to the controller 160 to monitor and control process parameters. According to implementations, the controller 160 may control the parameters such as the frequency, the amplitude, and the phase of the non-sinusoidal bias to optimize the density and ion energy of the plasma PLA. For example, the controller 160 may select the specific frequency bandwidth of the non-sinusoidal bias according to process conditions or adjust the asymmetry of the waveform to improve the uniformity of the deposition. The controller 160 may be designed to dynamically change the waveform at specific time intervals to minimize the variability that occurs during the deposition and maintain a constant deposition thickness throughout the entire substrate. The controller 160 may detect and monitor a voltage value and a current value of a bias power signal applied to the substrate support 120.

The process gas supply 172 may be a device that supplies the process gas required for forming the plasma PLA inside the chamber 110. The process gas may be a non-reactive gas such as argon (Ar) or krypton (Kr), or a reactive process gas such as oxygen (O2) or nitrogen (N2). The process gas may be supplied to the chamber 110 through the gas supply line 174 and the gas inlet nozzle 176. The gas inlet nozzle 176 may be designed for uniform gas distribution and precise control of gas flow.

The vacuum pump 182 may be a device that maintains a high-vacuum state by removing air inside the chamber 110. The vacuum pump 182 may provide a low-pressure environment to form the plasm PLA during the process. The exhaust pipe 184 may be connected to the vacuum pump 182 and configured to discharge residual gas and particles to the outside of the chamber 110.

Each component of the substrate processing apparatus 100 described above and the substrate processing system using the same are not limited to the described example, but other components may be added or a part of the components may be changed or omitted.

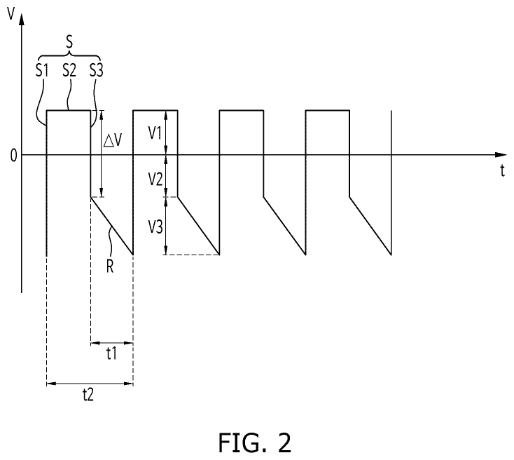

FIG. 2 is an exemplary view illustrating a non-sinusoidal bias voltage waveform according to implementations. Referring to FIG. 2, the power signal applied to the substrate support (e.g., 120 of FIG. 1) may have a periodic but non-sinusoidal bias voltage waveform. The bias power signal output from the non-sinusoidal bias supply (e.g., 150 of FIG. 1) may include a first portion S1, a second portion S2, a third portion S3, and a fourth portion R within one cycle. The first, second, and third portions S1, S2 and S3 may constitute a pulse period S, and the fourth portion R may constitute a ramp period. A ramp period R may be located between the pulse periods S, and represent a part modulated by a controller (e.g., 160 of FIG. 1). The ramp period R may have a waveform with a negative slope, which gradually decreases from a maximum value to a minimum value of the pulse period S.

The controller may control a positive voltage value V1, and a negative voltage value V2 of the pulse period S, a voltage value V3 of the ramp period R, a slope dV/dt of the ramp period R, an application time t1 of the ramp period R, a period t2 of one cycle, and a duty cycle through the bias control signal. The duty cycle is the time ratio between an active state of the periodic non-sinusoidal bias, during which the periodic non-sinusoidal bias is applied, and an inactive state of the non-sinusoidal bias, during which the periodic non-sinusoidal bias is not applied. The controller may efficiently control the deposition thickness uniformity, the plasma density, and the ion energy distribution by controlling the non-sinusoidal bias and precisely managing parameters such as a voltage value, a frequency of the cycle of the periodic non-sinusoidal bias signal, and a duty cycle.

For example, the frequency of the pulse period S may be adjusted within a range of 350 kHz to 450 kHz, the positive voltage value V1 may be adjusted within a range of 60 V to 180 V, and the negative voltage value V2 may be adjusted within a range of −50 V to −130 V. The voltage value V3 in the ramp period R may be adjusted within a range of −100 V to −600 V, and the application ratio t1/t2 of the ramp period R may be adjusted within a range of 45% to 55%. In the process, on/off frequencies of the non-sinusoidal waveform may be adjusted within a range of 10 Hz to 1000 Hz, and the duty cycle may be adjusted within a range of 40% to 60%, or 20% to 80%.

The voltage may be controlled to ensure uniform deposition on the surface of the substrate by adjusting the slope in the ramp period R of the non-sinusoidal waveform. Therefore, the plasma density and the ion energy may be optimized during the deposition process. The ion energy distribution with a gradual peak may be formed by adjusting the slope of the ramp period R, thereby improving the dispersion of the target particles. The uniformity of the deposition thickness may be improved by controlling an ion flux by adjusting the application time of ramp period R. The deposition quality and the production efficiency may be improved by adjusting the on/off duty cycle of the non-sinusoidal waveform during the process. Accordingly, the target particle distribution and the deposition profile controllability may be improved during the deposition process.

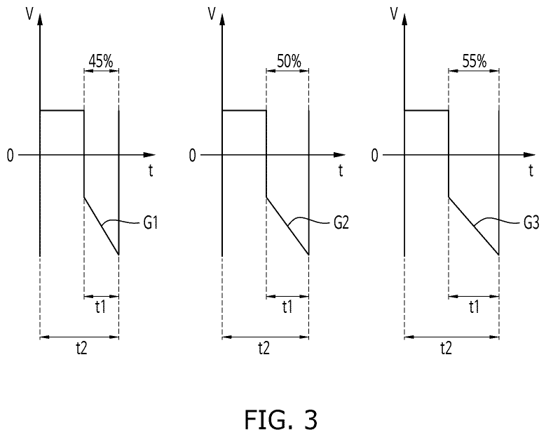

FIG. 3 illustrates graphs according to an application ratio in a ramp period. Referring to FIG. 3, a controller (e.g., 160 in FIG. 1) may adjust a time ratio t1/t2 of a voltage application time t1 of the ramp period to an entire voltage application time t2 within one cycle, i.e., a voltage application time ratio of the ramp period R. The voltage application time ratio of the ramp period R may be adjusted with a constant slope of the ramp period R, and the plasma density and the ion energy distribution may be controlled by changing the characteristics of the frequency and the waveform. For example, the controller may adjust the ratio of the voltage application time t1 of the ramp period to the entire voltage application time t2 of one cycle within a range of 45% to 55%.

Through the ratio adjustment of the ramp period R, the energy distribution of ions and electrons formed in the plasma may be precisely controlled. By adjusting the voltage application time ratio of the ramp period R, the impact that ion energies apply to the surface of the substrate may be precisely controlled, thereby improving the deposition uniformity and the quality of the thin film.

For example, when the total voltage application time t2 of one cycle is 2.5 μs, a first graph G1 may indicate a case where the voltage application time ratio of the ramp period R is adjusted to 45% (the application time t1 of the ramp period R is 1.125 μs). In this case, the plasma density may be relatively low, but the ion collision energy may be maintained constantly. A second graph G2 may indicate a case where the voltage application time ratio of the ramp period R is adjusted to 50% (the application time t1 of the ramp period R is 1.25 μs). In this case, the plasma density and ion energy may be balanced. A third graph G3 may indicate a case where the voltage application time ratio of the ramp period R is adjusted to 55% (the application time t1 of the ramp period R is 1.375 μs). In this case, as the ion density increases, the relatively high energy may be transmitted to the substrate, which is advantageous for increasing the deposition rate.

The adjustment of the voltage application time ratio of the ramp period R may provide various advantages in the plasma process, such as deposition uniformity, film thickness control, and minimization of damage to the surface caused by ion collision. For example, the first, second, and third graphs G1, G2, and G3 described above may represent cases where the voltage application time ratio of the ramp period R is adjusted to 45%, 50%, and 55%, respectively, which indicate that the plasma density and the ion energy may be controlled depending on process conditions.

The implementations may be examples of the voltage application time ratio of the ramp period R when the target TG is made of tungsten (W). In the case of the target TG including another material, such as copper (Cu), the ratio of the voltage application time t1 of the ramp period to the entire voltage application time t2 of one cycle may be adjusted within a range of 25% to 75%.

When the total voltage application time t2 in one cycle is 2.5 μs, and the target TG includes a material other than tungsten (W) (e.g., copper (Cu)), the voltage application time t1 of the ramp period R may be adjusted within a range of 0.625 μs (25%) to 1.875 μs (75%). Accordingly, the plasma density, the ion energy, and the deposition rate may be precisely controlled depending on the characteristics of the target materials to implement the deposition characteristic suitable for each process.

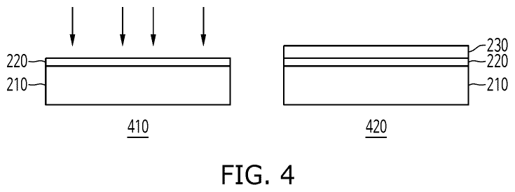

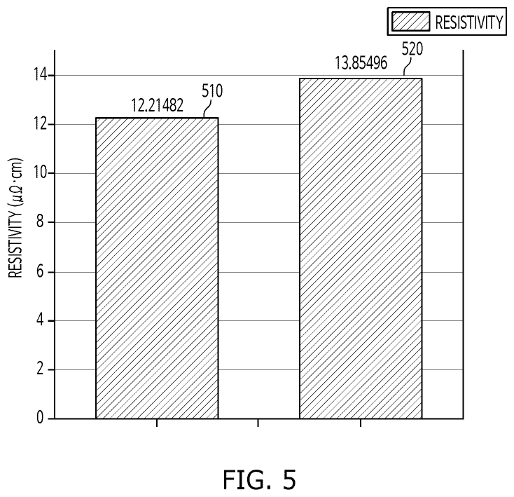

FIG. 4 is a view illustrating steps of the substrate processing process that uses the substrate processing apparatus according to implementations. FIG. 5 to FIG. 7 illustrate examples of the test results between a deposition layer 230 in FIG. 4 and a reference deposition layer. The reference deposition layer may be deposited by using a substrate processing apparatus where an RF bias is applied to a substrate support (e.g., 120 of FIG. 1) rather than a non-sinusoidal bias.

Referring to FIG. 4, a first example 410 illustrates that a process of performing a plasma treatment on a structure in which a silicide 220 is laminated on an insulating film 210 by using a substrate processing apparatus (e.g., 100 of FIG. 1) according to implementations of the present disclosure. Through the plasma treatment, the substrate surface may be activated, so that the adhesion of a deposition material may be improved in a subsequent deposition process. The insulating film 210 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and combinations thereof, but the present disclosure is not limited thereto. In addition, the silicide 220 may include tungsten silicide (WSi).

A second example 420 illustrates that a deposition layer 230 is deposited on the silicide 220. A deposition layer 230 may be uniformly deposited on a silicide layer through the PVD process. The deposition layer 230 may include tungsten (W).

The deposition process illustrated in FIG. 4 is exemplary for ease of explanation, the substrate processing apparatus according to the present disclosure may be used in various processes such as a deposition process of a metal thin film during the semiconductor device manufacturing process. For example, the substrate processing apparatus may be applied to various metal film forming processes such as a metal wiring formation, a contact plug formation, etc. in addition to a gate bit line formation.

Referring to FIG. 5 to FIG. 7, the test result of the deposition layer 230 formed according to the above-described implementations are detailed. In the substrate processing apparatus of the present disclosure, the frequency of the pulse period may be set within a range of 350 kHz to 450 kHz, the positive voltage value V1 may be set within a range of 60 V to 180 V, and the negative voltage value V2 may be set within a range of −50 V to −130 V. In addition, the voltage value V3 of the ramp period R may be set within a range of −100 V to −600 V, and the application ratio t1/t2 of the ramp period R may be set within a range of 45% to 55%. In the process, the on/off frequency of the non-sinusoidal waveform may be set within a range of 10 Hz to 1000 Hz, and the duty cycle may be set within a range of 40% to 60%.

FIG. 5 illustrates the result of a resistivity for the deposition layer 230 in FIG. 4 and the reference deposition layer. Referring to FIG. 5, the resistivity value (510) of the deposition layer 230 may be approximately 12.21 micro-ohm centimeter, and the resistivity value (520) of the reference deposition layer may be approximately 13.85 micro-ohm centimeter. This indicates that the resistivity may be improved by about 11.8% in the apparatus to which the implementations of the present disclosure are applied. The improvement in the resistivity value may be possible because the non-sinusoidal bias controls the plasma density and the ion energy more precisely to increase the uniformity and the density of the deposition layer.

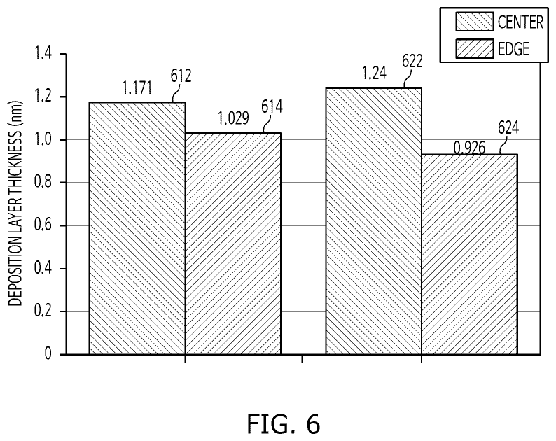

FIG. 6 illustrates the test result of the deposition thickness of the deposition layer 230 in FIG. 4 and the reference deposition layer. Referring to FIG. 6, the thickness of the deposition layer 230 may be 1.171 nanometers in the center region (a center, 612) and 1.029 nanometers in the edge region (an edge, 614), and the thickness of the reference deposition layer may be 1.24 nanometers in the center region (a center, 622) and 0.926 nanometers in the edge region (an edge, 624). Therefore, in the apparatus to which the non-sinusoidal bias is applied, the thickness difference between the center region and the edge region may be reduced, thereby improving the deposition uniformity. This may be because the non-sinusoidal bias may induce the uniform distribution of plasma, which contributes to forming a thin film with a uniform thickness throughout the entire the substrate.

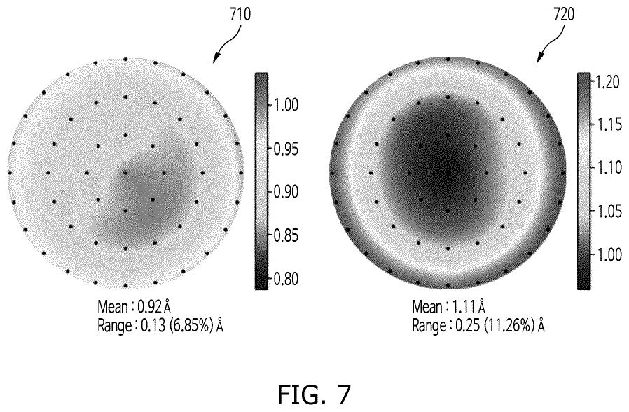

FIG. 7 illustrates the test result of the deposition thickness dispersion of the deposition layer 230 in FIG. 4 and the reference deposition layer. Referring to FIG. 7, the mean thickness of the deposition layer 230 may be 0.92 angstroms, and the dispersion range may be 0.13 angstroms (6.85%) (710). In the reference deposition layer, the mean thickness of the control deposition layer may be 1.11 angstroms, and the dispersion range may be 0.25 angstroms (11.26%) (720). This indicates that the apparatus to which the non-sinusoidal bias is applied may reduce the deviation of the deposition thickness to achieve more uniform deposition. The test result indicates that the density and ion energy distribution of the plasma may be precisely adjusted through the non-sinusoidal bias control by the controller, thereby enhancing the deposition uniformity and the process stability on the substrate surface.

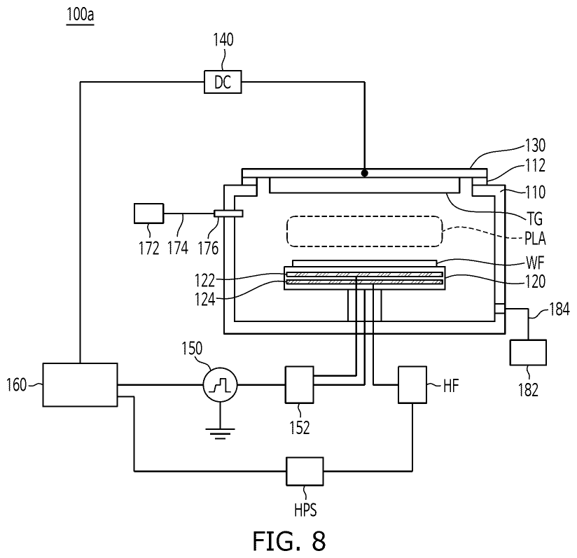

FIG. 8 is a view illustrating a substrate processing apparatus 100a according to implementations of the present disclosure. The substrate processing apparatus 100a described referring to FIG. 8 may be substantially the same as the substrate processing apparatus 100 described referring to FIG. 1 to FIG. 7 except for having a heater 124, a heater power HPS, and a heater filter HF.

The substrate processing apparatus 100a may include a chamber 110, a substrate support 120, an adsorption electrode 122, a heater 124, a target holder 130, a target TG, a DC power supply 140, a non-sinusoidal bias supply 150, a non-sinusoidal bias filter 152, a controller 160, a process gas supply 172, a gas supply line 174, a gas inlet nozzle 176, a vacuum pump 182, an exhaust pipe 184, a heater power HPS, and a heater filter HF.

The adsorption electrode 122 may fix the substrate WF in place by an electrostatic adsorption force generated when a voltage is applied. The heater 124 may control the temperature of the substrate support 120 by discharging heat when the voltage is applied.

According to implementations, the heater filter HF may be placed between the heater power HPS and the heater 124. The heater filter HF may reduce or block electrical disruption or noises generated between the heater 124 and the substrate support 120. For example, the heater filter HF may prevent the high-frequency property and electrical noise generated in the heater power HPS from being transmitted to the substrate support 120, or prevent the signal applied to the substrate support 120 from the non-sinusoidal bias supply 150 from affecting the heater 124.

Therefore, the heater 124 may stably operate and uniformly maintain the temperature of the substrate support 120, thereby improving the uniformity of the thickness of the thin film deposited on the substrate WF and the deposition dispersion.

The heater filter HF may prevent the electrical disruption generated from the heater 124 from being transmitted to the other system components or the power supply unit, thereby increasing the stability and reliability of the substrate processing apparatus 100a.

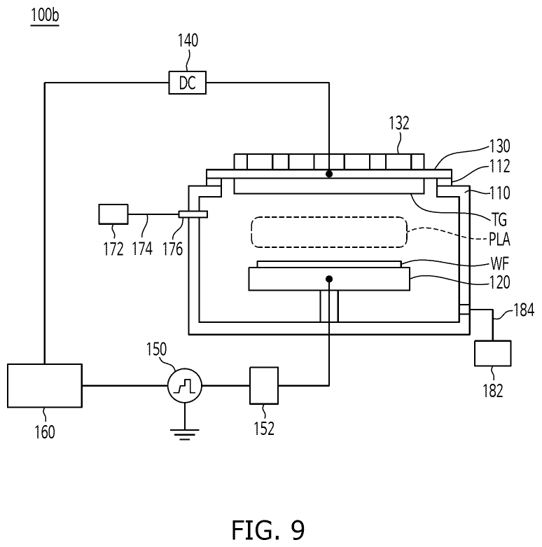

FIG. 9 is a view illustrating a substrate processing apparatus 100b according to implementations of the present disclosure. The substrate processing apparatus 100b described referring to FIG. 9 may be substantially the same as the substrate processing apparatuses 100 and 100a described referring to FIG. 1 to FIG. 8 except for having a permanent magnet 132.

The substrate processing apparatus 100b may include a chamber 110, a substrate support 120, a target holder 130, a permanent magnet 132, a target TG, a DC power supply 140, a non-sinusoidal bias supply 150, a non-sinusoidal bias filter 152, a controller 160, a process gas supply 172, a gas supply line 174, a gas inlet nozzle 176, a vacuum pump 182, and an exhaust pipe 184.

The permanent magnet 132 may be disposed to be adjacent to the target holder 130. For example, the permanent magnet 132 may be disposed on one surface of the target holder 130. The target TG may be disposed on the other surface of the target holder 130. The permanent magnet 132 and the target TG may be disposed to face each other.

The permanent magnet 132 may be a permanent magnetic assembly including a permanent magnet 132, i.e., a magnetron assembly. The magnetron assembly may further include a motor that rotates the permanent magnet 132. The permanent magnet 132 may form a magnetic field near the target TG to allow electrons near the surface of the target TG to move along a spiral trajectory by the magnetic field. This may increase the time that the electrons remain near the surface of the target, so that the density of the plasma PLA may be increased and the ionization efficiency may be enhanced. Accordingly, the sputtering rate may be increased, and the deposition efficiency may be improved.

The DC power supply 140 may be connected to the target TG and may enable the target TG to be biased as a cathode. The process gas for sputter discharge that is supplied to the inside of the chamber 110 may be ionized to the plasma PLA, and the generated positive ions may accelerate to and collide with the target TG. The magnetic field generated by the permanent magnet 132 may focus the plasma PLA near the surface of the target TG to improve sputtering efficiency.

According to implementations, the density of the plasma PLA and the sputtering efficiency may be improved by applying a magnetron sputtering method, and the quality of the thin film and the deposition uniformity may be improved by controlling the ion energy through the non-sinusoidal bias. The life span of the target TG may be increased by using the permanent magnet 132, thereby increasing the reproducibility of the process.

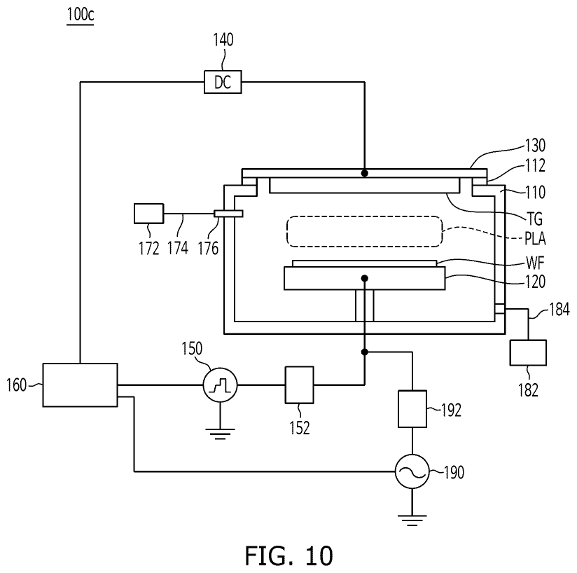

FIG. 10 is a view illustrating a substrate process apparatus 100c according to implementations. The substrate processing apparatus 100c described referring to FIG. 10 may be substantially the same as the substrate processing apparatuses 100, 100a, and 100b described referring to FIG. 1 to FIG. 9 except for having an RF bias supply 190 connected to the substrate support 120 and an RF filter 192.

The substrate processing apparatus 100c may include a chamber 110, a substrate support 120, a target holder 130, a target TG, a DC power supply 140, a non-sinusoidal bias supply 150, a non-sinusoidal filter 152, a controller 160, a process gas supply 172, a gas supply line 174, a gas inlet nozzle 176, a vacuum pump 182, an exhaust pipe 184, an RF bias supply 190 and an RF filter 192.

Referring to FIG. 10, the substrate processing apparatus 100c, unlike that of FIG. 1, the RF bias supply 190 may be further connected to the substrate support 120. Accordingly, the RF bias supply 190 may provide an RF bias to the substrate support 120. By adjusting the energy and density of the ions inside the plasma PLA through the RF bias applied to the substrate support 120, the characteristics of the deposited thin film may be improved, the deposition uniformity may be enhanced, and the damage to the substrate may be reduced.

The RF filter 192 may be connected between the RF bias supply 190 and the substrate support 120. The RF filter 192 may be designed to adjust the harmonic component of the RF bias, or selectively pass the signals in a specific frequency bandwidth. Therefore, the transmission effectivity of the RF bias may be improved, and unnecessary signals and noises may be removed to ensure the stability of the plasma PLA.

According to implementations, the RF bias or the non-sinusoidal bias may be selectively applied. The RF bias may adjust the energy and density of the ions inside the plasma PLA to improve the efficiency of the deposition process and the thin film characteristics. The non-sinusoidal bias may precisely adjust the ion energy distribution to improve the deposition uniformity and optimize the fine structure of the thin film.

The above-described configuration may diversify the power form applied to the substrate support 120 to obtain the optimal thin film characteristics according to process conditions. For example, a non-sinusoidal bias may be used when a high-density thin film or low defect density is required, and the RF bias may be used in a general thin film deposition.

The controller 160 may control at least one of the RF bias supply and the non-sinusoidal bias supply so that the RF bias or the non-sinusoidal bias may be selectively applied to the substrate support 120. For example, the controller 160 may control the power forms and the parameters respectively applied to the target TG and the substrate support 120 to implement various thin film characteristics.

According to implementations, the RF bias supply 190 and the non-sinusoidal bias supply 150 may be connected to the substrate support 120 to selectively apply the RF bias or the non-sinusoidal bias, thereby optimizing the deposition characteristic of the thin film and increasing the flexibility of the process. Therefore, the thin film of high quality may be formed, which contributes to productivity improvement and cost reduction in a semiconductor device manufacturing process.

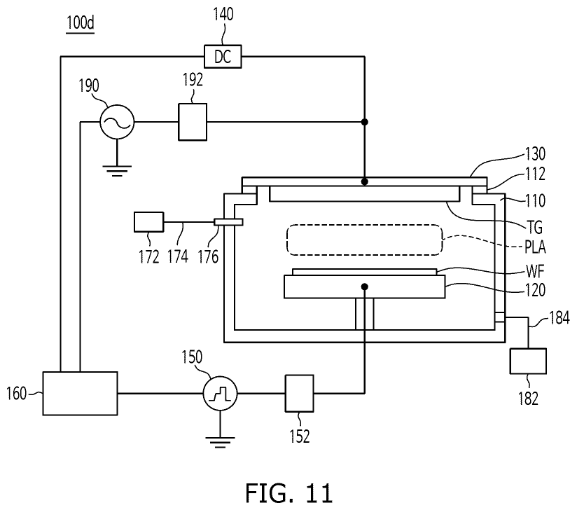

FIG. 11 is a view illustrating a substrate processing apparatus 100d according to implementations. Referring to FIG. 11, the substrate processing apparatus 100d may be substantially the same as the substrate processing apparatuses 100, 100a, and 100b described referring to FIG. 1 to FIG. 9 except having an RF bias supply 190 connected to the target TG and an RF filter 192.

The substrate processing apparatus 100d may include a chamber 110, a substrate support 120, a target holder 130, a target TG, a DC power supply 140, a non-sinusoidal bias supply 150, a non-sinusoidal filter 152, a controller 160, a process gas supply 172, a gas supply line 174, a gas inlet nozzle 176, a vacuum pump 182, an exhaust pipe 184, an RF bias supply 190, and an RF filter 192.

Referring to FIG. 11, unlike that of FIG. 1, in the substrate processing apparatus 100d, the RF bias supply 190 may be further connected to the target holder 130. The RF bias supply 190 may provide an RF bias to the target holder 130. The DC power supply 140 and the RF bias supply 190 may be connected to the target holder 130.

According to implementations, the plasma PLA may be generated and maintained by the DC power or the RF bias applied to the target holder 130. The DC power may be applied to a conductive target material to allow the target TG to be biased as a cathode, the ions inside the plasma PLA may collide with the target such that the target atoms may be sputtered. The RF bias may be applied to a non-conductive or insulating target material to prevent electron accumulation on the target surface and generate the stable plasma PLA to enable sputtering.

The RF filter 192 may be connected between the RF bias supply 190 and the target holder 130, and the RF filter 192 may be designed to control the harmonic components of the RF bias, and selectively pass the signals in a specific frequency bandwidth. Therefore, the transmission efficiency of the RF power may be improved, and unnecessary signals and noises may be removed to increase the stability of the plasma PLA.

According to implementations, the DC power or the RF bias may be selectively applied. Optimal sputtering condition may be embodied by selecting and applying the suitable power supply according to process requirements and characteristics of target materials. For example, in the case of a conductive target, the DC power may be applied to perform an efficient sputtering, and in the case of a non-conductive target, the RF bias may be applied to form the stable plasma PLA and perform an efficient sputtering.

The controller 160 may control at least one of the DC power supply and the RF bias supply, so that the DC power or the RF bias may be selectively applied to the target holder 130. For example, various thin film characteristics may be implemented by controlling the voltage and the current applied to the target TG, and the parameters of the non-sinusoidal bias applied to the substrate support 120.

Implementations of the present disclosure may correspond to various target materials and process conditions by selectively applying the DC power and the RF bias to the target holder 130. In addition, the energy distribution inside the plasma PLA may be finely controlled and the uniformity and quality of the deposited thin film may be improved by applying the non-sinusoidal bias to the substrate support 120.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to exemplary implementations thereof, it is to be understood that the present disclosure is not limited to the exemplary implementations. It will be apparent to those skilled in the art that various modifications and changes may be made within the scope of the appended claims and their equivalents.

What is claimed is:

1. A substrate processing apparatus, comprising:
a chamber configured to maintain a substrate processing process;
a substrate support inside the chamber and configured to support a substrate;
a target within the chamber and facing the substrate;
a target holder connected to the target;
a non-sinusoidal bias supply configured to provide a periodic non-sinusoidal bias to the substrate support;
a DC power supply configured to apply a DC power to the target through the target holder; and
a controller configured to control a waveform of the periodic non-sinusoidal bias,
wherein the periodic non-sinusoidal bias includes, within one cycle, a pulse period during which a voltage is maintained constantly and a ramp period during which the voltage gradually changes.

2. The substrate processing apparatus of claim 1, wherein the controller is configured to determine a non-sinusoidal parameter including a positive voltage value and a negative voltage value of the pulse period, a voltage value of the ramp period, and a voltage application time.

3. The substrate processing apparatus of claim 1, wherein the controller is configured to control a ratio of a voltage application time of the ramp period to an entire voltage application time of the cycle to be within a range from 45% to 55%.

4. The substrate processing apparatus of claim 1, wherein the controller is configured to control a positive voltage of the pulse period to be within a range from 10V to 50V.

5. The substrate processing apparatus of claim 1, wherein the controller is configured to control a negative voltage of the pulse period to be within a range from −50V to −130V.

6. The substrate processing apparatus of claim 1, wherein the controller is configured to control a duty cycle to be within a range from 40% to 60%, wherein the duty cycle is a ratio between an active state of the periodic non-sinusoidal bias and a non-active state.

7. The substrate processing apparatus of claim 1, wherein the controller is configured to control a waveform of the periodic non-sinusoidal bias based on a dispersion of particles of the target deposited to the substrate.

8. The substrate processing apparatus of claim 1, wherein the target comprises at least one metal from a group of metals consisting of copper, titanium, and tungsten.

9. The substrate processing apparatus of claim 1, wherein the substrate processing process comprises a deposition process.

10. The substrate processing apparatus of claim 1, further comprising an RF bias supply configured to provide an RF bias to the substrate support.

11. The substrate processing apparatus of claim 10, wherein the controller is configured to control the RF bias supply to allow the RF bias to be applied to the substrate support, and to control the non-sinusoidal bias supply to allow the periodic non-sinusoidal bias to be applied to the substrate support.

12. The substrate processing apparatus of claim 1, wherein the DC power supply is configured to bias the target as a cathode.

13. The substrate processing apparatus of claim 12, further comprising an RF bias supply configured to provide an RF bias to the target holder.

14. The substrate processing apparatus of claim 13, wherein the controller is configured to control the DC power supply to allow the DC power to be applied to the target holder and to control the RF bias supply to allow the RF bias to be applied to the target holder.

15. The substrate processing apparatus of claim 1, further comprising a permanent magnet adjacent to the target holder.

16. The substrate processing apparatus of claim 1, further comprising a process gas supply configured to provide a plasma process gas inside the chamber.

17. The substrate processing apparatus of claim 16, wherein the plasma process gas includes argon or krypton.

18. The substrate processing apparatus of claim 1, further comprising a non-sinusoidal filter between the non-sinusoidal bias supply and the substrate support,
wherein the non-sinusoidal filter is configured to selectively filter a frequency component of the periodic non-sinusoidal bias.

19. A substrate processing apparatus, comprising:
a chamber configured to maintain a deposition process;
a substrate support inside the chamber and configured to support a substrate;
a target, within the chamber and facing the substrate;
a target holder connected to the target;
a permanent magnet adjacent to the target holder;
a non-sinusoidal bias supply configured to provide a periodic non-sinusoidal bias to the substrate support;
a DC power supply configured to apply a DC power to the target through the target holder; and
a controller configured to control a waveform of the periodic non-sinusoidal bias,
wherein the periodic non-sinusoidal bias includes, within one cycle, a pulse period during which a voltage is constantly maintained, and a ramp period during which the voltage gradually changes, and
wherein the controller is configured to control a non-sinusoidal parameter including a positive voltage value and a negative voltage value of the pulse period, a voltage value of the ramp period, and a voltage application time.

20. A substrate processing apparatus, comprising:
a chamber configured to maintain a deposition process;
a substrate support inside the chamber and configured to support a substrate;
a target within the chamber and facing the substrate;
a target holder connected to the target;
a permanent magnet adjacent to the target holder;
a non-sinusoidal bias supply configured to provide a periodic non-sinusoidal bias to the substrate support;
a non-sinusoidal filter between the non-sinusoidal bias supply and the substrate support and configured to selectively filter a frequency component of the periodic non-sinusoidal bias;
a DC power supply configured to apply a DC power to the target through the target holder;
an RF bias supply configured to provide an RF bias to the target holder or to the substrate support; and
a controller configured to control a waveform of the periodic non-sinusoidal bias,
wherein the periodic non-sinusoidal bias includes, within one cycle, a pulse period during which a voltage is constantly maintained, and a ramp period during which the voltage gradually changes, and
wherein the controller is configured to control a non-sinusoidal parameter including a positive voltage value and a negative voltage value of the pulse period, a voltage value of the ramp period, and a voltage application time.
